(19) United States
(12) Patent Application Publication
(10) Pub. No.: US 2019/0131585 A1
(43) Pub. Date: May 2, 2019

(54) APPARATUS OF PECVD AND MANUFACTURING METHOD OF OLED PANEL

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Zhongguo YANG, Shenzhen, Guangdong (CN); Jinchuan LI, Shenzhen, Guangdong (CN)

(21) Appl. No.: 15/741,880

(22) PCT Filed: Nov. 29, 2017
(86) PCT No.: PCT/CN2017/113569

§ 371 Date: Jan. 4, 2018

(30) Foreign Application Priority Data
Nov. 1, 2017 (CN) 201711058780.5

(51) Int. Cl. H01L 51/56; C23C 16/455; C23C 16/458; C23C 16/50; H01L 51/52

(52) U.S. Cl. CPC H01L 51/56; C23C 16/45563; H01L 51/5253; C23C 16/50; C23C 16/4584

(57) ABSTRACT

The present invention provides a plasma enhanced chemical vapor deposition apparatus and an encapsulation method of an OLED panel. A straight line extending in an extending direction of the cathode of the plasma enhanced chemical vapor deposition apparatus oblique to the horizontal plane. The anode plate, the grid plate and the insulating plate are provided with the channel communicating with the cavity and extending in the same direction as the extending direction of the cathode. Therefore, the rotating shaft is driven to rotate the OLED substrate, inert gas or nitrogen gas is injected into the cavity, and a first reaction gas is injected under one end of the channel near to the base. A second reaction gas is injected under the anode plate through the second reaction gas injection port and a direct current voltage is applied between the anode plate and the cathode.

### RELATED APPLICATIONS

The present application is a National Phase of International Application Number PCT/CN2017/113569, filed on Nov. 29, 2017, and claims the priority of China Application 201711058780.5, filed on Nov. 1, 2017.

### FIELD OF THE DISCLOSURE

The disclosure relates to a technical field of manufacturing display device, and more particularly to a plasma enhanced chemical vapor deposition apparatus and an encapsulation method of an OLED panel.

### BACKGROUND

The Organic Light Emitting Display (OLED) possesses many outstanding properties of self-illumination, low driving voltage, high luminescence efficiency, short response time, high clarity and contrast, near 180° view angle, wide range of working temperature, applicability of flexible display and large scale full color display, etc. The OLED is considered as the most potential display device.

The OLED can be categorized into two major types according to the driving ways, which are the Passive Matrix OLED (PMOLED) and the Active Matrix OLED (AMOLED), i.e., two types of the direct addressing and the Thin Film Transistor (TFT) matrix addressing. The AMOLED comprises pixels arranged in array and belongs to active display type, which has high lighting efficiency and is generally utilized for the large scale display devices of high clarity.

The OLED display is different from the traditional liquid crystal display in that the back light is not required. It utilizes an ultra thin organic material coating layer and a glass substrate, and theses organic material will illuminate when the current is conducted. However, because the organic materials are easy to react with water vapor or oxygen gas, as a display device based on the organic materials, the OLED display panel has strict requirements for encapsulating. Therefore, it is crucially important for the steady lighting of the OLED element to be isolated from external environment as possible as it can by promoting the tightness of the element interior by encapsulation of the OLED element. In the prior art, the OLED device is often encapsulated in a film encapsulation manner to prevent from the intrusion of water and oxygen into the OLED device. Generally, the film encapsulation manner is to sequentially and alternately overlap on the OLED substrate having the OLED device to form an inorganic barrier layer having a good water and oxygen insulation property, and an organic buffer layer having a good flexibility so as to form an encapsulation structure. The inorganic barrier layer is used for blocking external water and oxygen, and the organic buffer layer is used for releasing the stresses between the adjacent barrier layers. In general, silicon nitride (SiNₓ) is used as the material of the inorganic barrier layer, which is made on the OLED device by the Plasma Enhanced Chemical Vapor Deposition (PECVD). The existing plasma enhanced chemical vapor deposition apparatuses all are a parallel plate type, the so-called parallel plate type, which disposes the lower electrode having a ground potential, and a high-frequency electrode located above and parallel to the lower electrode. The substrate on which an inorganic layer is to be deposited is disposed on the lower electrode. The high-frequency electrode is provided with a large number of openings. The reaction gas is ejected vertically downward from the plurality of openings to generate plasma under the action of a high-frequency electric field between the lower electrode and the high-frequency electrode, and most of the plasma is generated in a direction perpendicular to the lower electrode and the high-frequency electrode so as to form the inorganic layer on the substrate.

Please refer to FIG. 1, FIG. 1 is a schematic structural view of a conventional large-size OLED display. In the large-size OLED display, isolation pillars 200′ having an inverted trapezoid in its cross section are usually disposed on the OLED substrate 100′ for joining the cathode of the OLED device on the OLED substrate 100′ and the metal layer used for assisting the cathode. The inorganic barrier layer 300′ in the thin film encapsulation structure covers the OLED substrate 100′ and the isolation pillars 200′. Generally, the height of the isolation pillars 200′ is much larger than the thickness of the inorganic barrier layer 300′, in the thin film encapsulation structure, covering the isolation pillars 200′ and the OLED substrate 100′, which makes the thickness of the inorganic barrier layer 300′ at the sidewall of the isolation pillars 200 reduced or even disconnected when the inorganic barrier layer 300′ is deposited by the use of the parallel plate type plasma enhanced chemical vapor deposition apparatus. Accordingly, a channel of ingress for water and oxygen is generated to deteriorate the encapsulation effect.

### SUMMARY

An objective of the present invention is to provide a plasma enhanced chemical vapor deposition apparatus. When the OLED substrate is encapsulated by using the plasma enhanced chemical vapor deposition apparatus, a continuous inorganic barrier layer can be deposited on the OLED substrate having isolation pillars on the surface of the OLED substrate to improve the encapsulation effect.

Another objective of the present invention is to provides the encapsulation method of the OLED panel of the present invention which can deposit a continuous inorganic barrier layer on the OLED substrate having isolation pillars on the surface to improve the encapsulation effect.

To realize the above mentioned objects, the present invention first provides a plasma enhanced chemical vapor deposition apparatus, comprising: a base, a rotating shaft fixed on a lower surface of the base, and a plurality of reaction units disposed over the base.

Each of said reaction units comprises a horizontal anode plate, a cavity defining layer disposed over said anode plate, a columnar cathode disposed over said anode plate, and a plurality of grid plates and insulating plates disposed between said anode plate and said cavity defining layer as well as said cathode and sequentially and alternately overlapped from bottom to top.

Said cavity defining layer is provided with a cavity penetrating said cavity defining layer, and said cathode is accommodated in said cavity. Said anode plate and said plurality of grid plates and insulating plates are provided with channels communicating with said cavity; a straight line where an extending direction of said cathode is located is oblique to a horizontal plane, and an extending direction of said channel is consistent with said extending direction of said cathode.

Each of said reaction unit further comprises: a first reaction gas injection port provided at one end of said channel near to said base, a gas inlet provided at one end of the cavity far away from said base, and a second reaction gas injection port provided under said anode plate; said gas inlet is used for introducing inert gas or nitrogen gas into said cavity; said first reaction gas injection port is used for injecting a first reaction gas under one end of said channel near to said base; said second reaction gas injection port is used for injecting a second reaction gas under said anode plate.

Said second reaction gas injection port injects said second reaction gas under said anode plate from top to bottom, and an included angle between a straight line where said second reaction gas is injected under said anode plate and said horizontal plane is smaller than an included angle between a straight line where said extending direction of said channel is located and said horizontal plane.

Said inert gas is argon gas, said first reaction gas is a mixed gas of one or more of ammonia gas, hydrogen gas; and nitrous oxide gas; and said second reaction gas is silane.

A direction of said inert gas or said nitrogen gas introduced into said cavity by said gas inlet is consistent with said extending direction of said cathode.

Said extending direction of said cavity is consistent with said extending direction of said cathode.

The present invention further provides an encapsulation method of an OLED panel, comprising the following steps:

step S1, providing said plasma enhanced chemical vapor deposition apparatus, a mask plate, and an OLED substrate;

said OLED substrate is provided with a plurality of isolation pillars;

step S2, disposing said OLED substrate on said base, aligning said mask plate with said OLED substrate, and fixing said mask plate on said base;

step S3, driving said rotating shaft to rotate said base and said OLED substrate on said base; utilizing an gas inlet to inject inert gas or nitrogen gas into a cavity, utilizing a first reaction gas injection port to inject a first reaction gas under one end of a channel near to said base, utilizing a second reaction gas injection port to inject a second reaction gas under said anode plate; and

step S4, keeping the rotation of the rotating shaft, and keeping the introduction of said inert gas or said nitrogen gas and the injection of said first and second reaction gases to apply a direct current voltage between said anode plate and said cathode, so as to make plasma of said inert gas or said nitrogen gas ejected from said end of said channel near to said base in an extending direction of said channel, thereby reacting said first reaction gas with said second reaction gas to form an inorganic barrier layer covering said isolation pillars on said OLED substrate.

In said step S3 and said step S4, said second reaction gas injection port injects said second reaction gas under said anode plate from top to bottom, and an included angle between a straight line where said second reaction gas is injected under said anode plate and said horizontal plane is smaller than an included angle between a straight line where said extending direction of said channel is located and said horizontal plane.

A cross-sectional shape of said isolation pillars is an inverted trapezoid, and an acute angle between a side surface of said isolation pillars and said horizontal plane is greater than an included angle between a straight line where said extending direction of said channel is located and a horizontal plane.

Said inert gas is argon gas, said first reaction gas is a mixed gas of one or more of ammonia gas, hydrogen gas, and nitrous oxide gas, and said second reaction gas is silane.

In said step S3 and said step S4, a direction of said inert gas or said nitrogen gas introduced into said cavity by said gas inlet is consistent with said extending direction of said cathode.

Said extending direction of said cavity is consistent with said extending direction of said cathode.

The present invention further provides a plasma enhanced chemical vapor deposition apparatus, comprising: a base, a rotating shaft fixed on a lower surface of the base, and a plurality of reaction units disposed over the base.

Each of said reaction units comprises a horizontal anode plate, a cavity defining layer disposed over said anode plate, a columnar cathode disposed over said anode plate, and a plurality of grid plates and insulating plates disposed between said anode plate and said cavity defining layer as well as said cathode and sequentially and alternately overlapped from bottom to top.

Said cavity defining layer is provided with a cavity penetrating said cavity defining layer, and said cathode is accommodated in said cavity. Said anode plate and said plurality of grid plates and insulating plates are provided with channels communicating with said cavity, a straight line where an extending direction of said cathode is located is oblique to a horizontal plane, and an extending direction of said channel is consistent with said extending direction of said cathode.

Each of said reaction unit further comprises: a first reaction gas injection port provided at one end of said channel near to said base, a gas inlet provided at one end of the cavity far away from said base, and a second reaction gas injection port provided under said anode plate; said gas inlet is used for introducing inert gas or nitrogen gas into said cavity; said first reaction gas injection port is used for injecting a first reaction gas under one end of said channel near to said base; said second reaction gas injection port is used for injecting a second reaction gas under said anode plate;

wherein said second reaction gas injection port injects said second reaction gas under said anode plate from top to bottom, and an included angle between a straight line where said second reaction gas is injected under said anode plate and said horizontal plane is smaller than an included angle between a straight line where said extending direction of said channel is located and said horizontal plane;

wherein said inert gas is argon gas, said first reaction gas is a mixed gas of one or more of ammonia gas, hydrogen gas; and nitrous oxide gas, and said second reaction gas is silane;

wherein a direction of said inert gas or said nitrogen gas introduced into said cavity by said gas inlet is consistent with said extending direction of said cathode;

wherein said extending direction of said cavity is consistent with said extending direction of said cathode.

The benefits of the present invention are: the plasma enhanced chemical vapor deposition apparatus provided by the present invention has a straight line, extending in an extending direction of the cathode, oblique to the horizontal plane. The anode plate, the grid plate and the insulating plate are provided with the channel communicating with the cavity and extending in the same direction as the extending direction of the cathode. Therefore, when the apparatus is used for encapsulating an OLED panel, the rotating shaft is driven to rotate the OLED substrate, inert gas or nitrogen gas is injected into the cavity, and a first reaction gas is injected under one end of the channel near to the base. A second reaction gas is injected under the anode plate through the second reaction gas injection port and a direct current voltage is applied between the anode plate and the cathode, so that a plasma of inert gas or nitrogen gas is ejected from the end of the channel near the base in an extending direction of the channel to react the first reaction gas with the second reaction gas to form a continuous inorganic barrier layer on the surface of the OLED substrate having the isolation pillar, which effectively improves the encapsulation effect. In the encapsulation method of the OLED panel provided by the present invention, the above-mentioned plasma enhanced chemical vapor deposition apparatus can deposit a continuous inorganic barrier layer on the OLED substrate having isolation pillars on the surface to improve the encapsulation effect.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a schematic structural view of a conventional large-size OLED display;

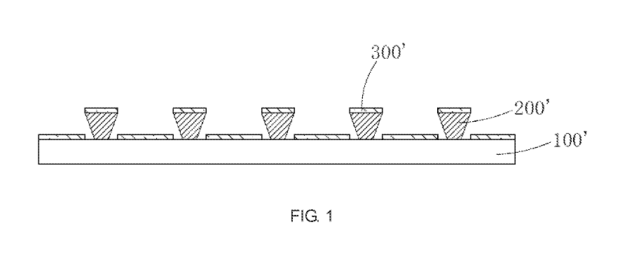

FIG. 2 is a schematic structural view of the plasma enhanced chemical vapor deposition apparatus of the present invention;

FIG. 3 is a schematic view of the reaction unit of the plasma enhanced chemical vapor deposition apparatus of the present invention;

FIG. 4 is a flow chart of an encapsulation method of an OLED panel of the present invention;

FIG. 5 is a schematic view of the step S1 and the step S2 of an encapsulation method of the OLED panel according to the present invention;

FIG. 6 is a schematic view of the step S3 of an encapsulation method of the OLED panel according to the present invention;

FIG. 7 is a schematic view of the step S4 of an encapsulation method of the OLED panel according to the present invention.

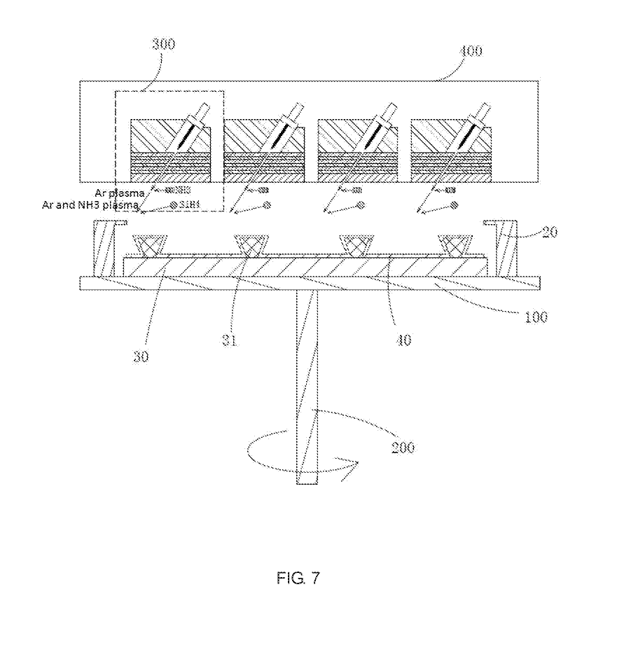

### DETAILED DESCRIPTION OF PREFERRED EMBODIMENTS

For better explaining the technical solution and the effect of the present invention, the present invention will be further described in detail with the accompanying drawings and the specific embodiments.

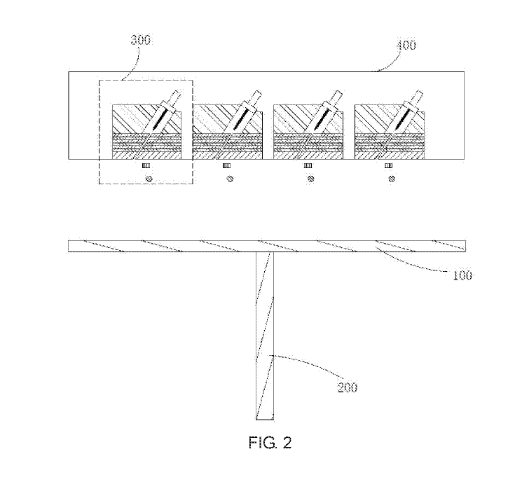

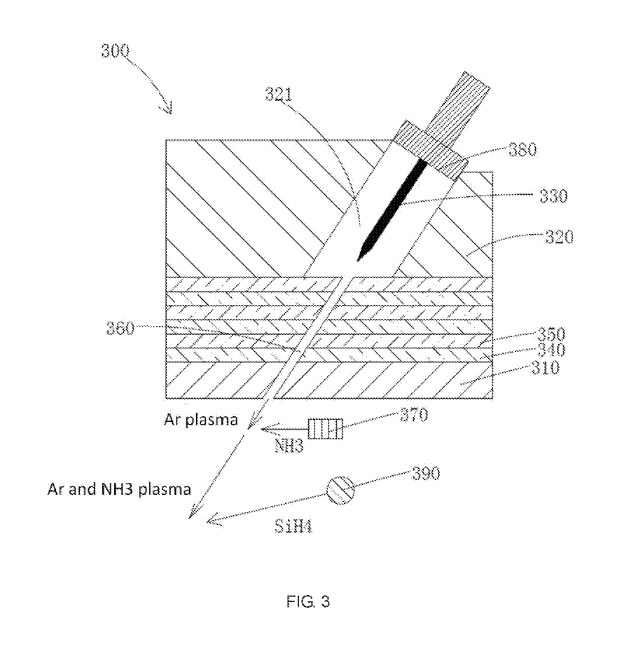

Please refer to FIGS. 2 and 3, the present invention provides a plasma enhanced chemical vapor deposition apparatus, comprising: a base 100, a rotating shaft 200 fixed on the lower surface of the base 100, and a plurality of reaction units 300 disposed over the base 100.

Each of said reaction units 300 comprises a horizontal anode plate 310, a cavity defining layer 320 disposed over said anode plate 310, a columnar cathode 330 disposed over said anode plate 310, and a plurality of grid plates 340 and insulating plates 350 disposed between said anode plate 310 and said cavity defining layer 320 and said cathode 330 and sequentially and alternately overlapped from bottom to top.

Said cavity defining layer 320 is provided with a cavity 321 penetrating said cavity defining layer 320, and said cathode 330 is accommodated in said cavity 321; said anode plate 310 and said plurality of grid plates 340 and insulating plates 350 are provided with channels 360 communicating with said cavity 321, a straight line where an extending direction of said cathode 330 is located is oblique to a horizontal plane, and an extending direction of said channel 360 is consistent with said extending direction of said cathode 330.

Each of said reaction unit 330 further comprises: a first reaction gas injection port 370 provided at one end of said channel 360 near to said base 100, a gas inlet 380 provided at one end of the cavity 321 far away from said base 100, and a second reaction gas injection port 390 provided under said anode plate 310; said gas inlet 380 is used for introducing inert gas or nitrogen gas into said cavity 321; said first reaction gas injection port 370 is used for injecting a first reaction gas under one end of said channel 360 near to said base 100; said second reaction gas injection port 390 is used for injecting a second reaction gas under said anode plate 310.

Specifically, said plurality of reaction units 300 are evenly arranged above the base 100 to generate a more uniform film-forming effect.

Specifically, the plasma enhanced chemical vapor deposition apparatus as a whole is accommodated in a reaction chamber (not shown).

Specifically, referring to FIG. 2, said plasma enhanced chemical vapor deposition apparatus further comprises a reaction unit housing 400. A bottom surface of said reaction unit housing 400 is located on a bottom surface of the anode plates 310 of the plurality of reaction units 300. The sidewalls and the top surface cover a plurality of reaction units 300, and the housing 400 is also provided with openings each corresponding to each of the reaction units 300 to exposing the channels 360. The reaction unit housing 400 is used for the protection of the plurality of reaction units 300.

Specifically, please refer to FIG. 3, in the preferred embodiment of the present invention, the gas introduced into the cavity 321 through said gas inlet 380 is an inert gas, and said inert gas is argon (Ar) gas. Said first reaction gas is ammonia gas (NH₃) and said second reaction gas is silane (SiH₄). Correspondingly, the inorganic film formed by the deposition of the plasma enhanced chemical vapor deposition apparatus is a silicon nitride film. Of course, the gas introduced into the cavity 321 through the gas inlet 380 may also be nitrogen gas or other inert gases other than argon gas, which will not affect the implementation of the present invention. In addition to ammonia, a mixed gas selected from hydrogen gas, nitrous oxide gas, ammonia gas, hydrogen gas, and nitrous oxide gas, or other common reaction gases used in a CVD process can be selected as the first reaction gas. In addition to silane, other common reaction gases used in the chemical vapor deposition process may be selected as the second reaction gas, so that the plasma enhanced chemical vapor deposition apparatus may correspondingly deposit to form inorganic films, such as silicon oxide films, silicon oxynitride films and the like, of other materials often produced in an existing plasma enhanced chemical vapor phase deposition technology.

Preferably, please refer to FIG. 2 and FIG. 3, the direction of the inert gas or the nitrogen gas introduced into the cavity 321 by said gas inlet 380 is consistent with the extending direction of the cathode 330, and said extending direction of said cavity 321 is consistent with said extending direction of said cathode 330.

With the example of the gas introduced into the cavity 321 through the gas inlet 380 being an inert gas which is argon gas, said first reaction gas being ammonia gas and said second reaction gas being silane, the operation steps of the plasma enhanced chemical vapor deposition apparatus of the present invention are: first, the substrate on which the inorganic film is to be formed is provided on the base 100, and the corresponding mask is aligned with the substrate on which the inorganic film is to be formed to fix the mask on the base 100. The rotating shaft 200 is then driven to rotate the base 100 and the substrate on which the inorganic film to be formed. At the same time, argon gas is introduced into the cavity 321 through the gas inlet 380, ammonia gas is injected through the first reaction gas injection port 370 under one end of the channel 360 near to the base 100, and silane is injected through the second reaction gas injection port 390 under the anode plate 310 to form a film-forming atmosphere in the reaction chamber. Then, the introduction of argon gas and the injection of ammonia gas and silane are kept, and the rotation of the rotating shaft 200 is kept. A direct current voltage is applied between the anode plate 310 and the cathode 330 to generate an electric field, so that the argon gas is converted into the plasma of the argon gas and ejected from one end of the channel 360 near to the base 100 in the extending direction of the channel 360, and the ammonia gas injected into the channel 360 near to the one end of the base 100 is converted to a plasma of the ammonia gas and mixed with a plasma of the argon gas to continue to be ejected under the anode plate 310 in the extending direction of the channel 360, so that the injected silane under the anode plate 310 becomes a plasma of the silane and reacts with the plasma of the ammonia gas to form a silicon nitride film on the substrate on which the inorganic film is to be formed. At the same time, Since the argon plasma is emitted in the extending direction of the channel 360 and the substrate to be formed with the inorganic film is kept rotated during the film formation, even though the substrate having the inorganic film to be formed has a height greater than the thickness of the formed silicon nitride film, the isolation pillars and the formed silicon nitride film on the side surface of the isolation pillars are not be thinned or broken by the existence of the isolation pillar. Therefore, when the plasma enhanced chemical vapor deposition apparatus of the present invention is applied to formation of an inorganic barrier layer in an encapsulation structure in an encapsulation process of a large-size OLED panel, a continuous inorganic barrier layer covering the isolation pillars can be formed on the OLED substrate having the isolation pillars on the surface so as to effectively enhance encapsulation effect.

Preferably, please refer to FIG. 3, said second reaction gas injection port 390 injects said second reaction gas under said anode plate 310 from top to bottom, and an included angle between a straight line where said second reaction gas is injected under said anode plate 310 and said horizontal plane is smaller than an included angle between a straight line where said extending direction of said channel 360 is located and said horizontal plane. Further, that the thickness of the silicon nitride film on the side surface of the isolation pillars is not thinned or broken is ensured, so as to further improve the encapsulation effect.

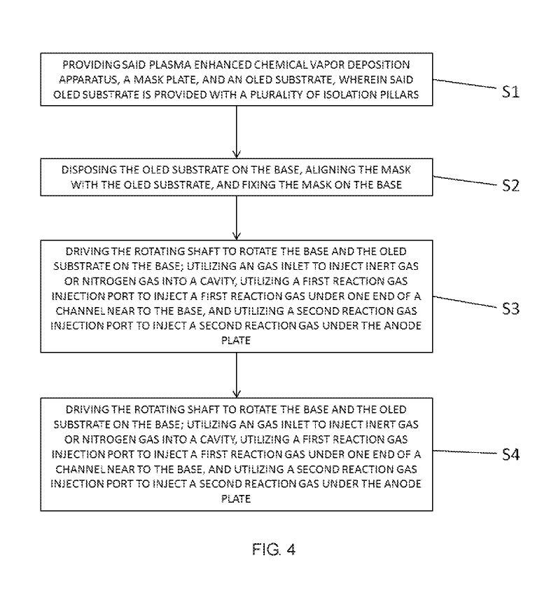

Please refer to FIG. 4, based on the same inventive concept, the present invention further provides an encapsulation method of an OLED panel, comprising the following steps:

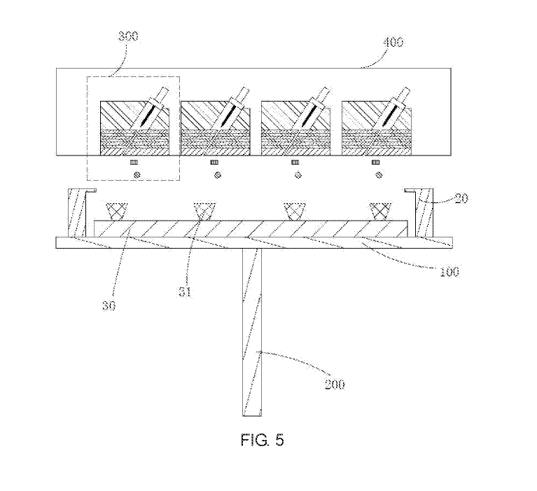

step S1, please refer to FIG. 5 as well as FIGS. 2 and 3, said plasma enhanced chemical vapor deposition apparatus, a mask plate 20, and an OLED substrate 30 are provided.

wherein the OLED substrate 30 is provided with a plurality of isolation pillars 31 for joining the cathode of the OLED substrate and a metal layer used for assisting the cathode.

Specifically, please refer to FIG. 5, the cross-sectional shape of said isolation pillars 31 is an inverted trapezoid. An acute angle between a side surface of said isolation pillars 31 and said horizontal plane is greater than an included angle between a straight line where said extending direction of said channel 360 is located and a horizontal plane.

Specifically, said extending direction of said cavity 321 is consistent with said extending direction of said cathode 330.

Step S2, please refer to FIG. 5, the OLED substrate 30 is disposed on the base 100, the mask 20 is aligned with the OLED substrate 30, and fixed on the base 100.

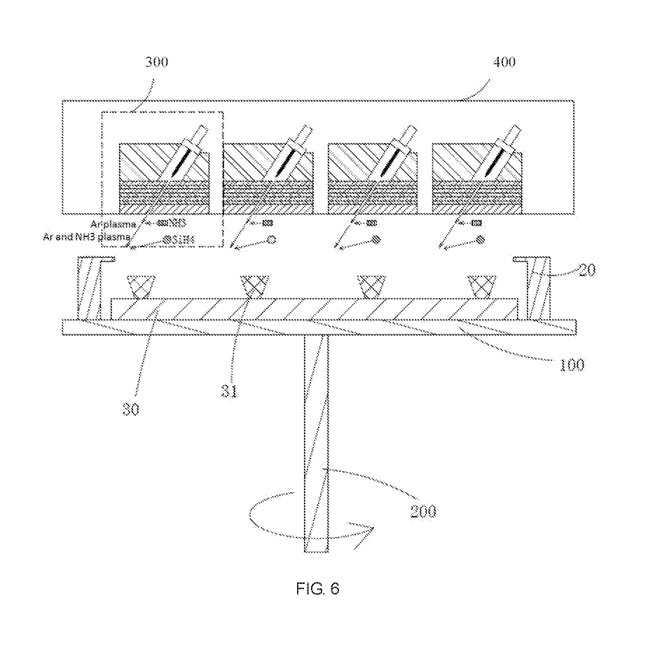

Step S3, please refer to FIG. 6, the rotating shaft 200 is driven to rotate the base 100 and the OLED substrate 30 on the base. The gas inlet 380 is utilized to introduce the inert gas or the nitrogen gas into a cavity 321, said first reaction gas injection port 370 is utilized to inject a first reaction gas under one end of said channel 360 near to said base 100. Said second reaction gas injection port 390 is utilized to inject a second reaction gas under said anode plate 310. The film-forming atmosphere is formed in the reaction chamber.

Specifically, in the preferred embodiment of the present invention, the gas introduced into the cavity 321 through said gas inlet 380 is an inert gas, and said inert gas is argon (Ar) gas. Said first reaction gas is ammonia gas, Said second reaction gas is silane. Correspondingly, in said step S3, the argon gas is introduced into the cavity 321 through the gas inlet 380, the ammonia gas is through the first reaction gas injection port 370 injected under the one end of the channel 360 near to the base 100, and the silane is injected through the second reaction gas injection port 390 under the anode plate 310 to form a film-forming atmosphere in the reaction chamber.

Preferably, in said step S3, the direction of the inert gas or nitrogen gas introduced into the cavity 321 by said gas inlet 380 is consistent with the extending direction of the cathode 330.

Step S4, the rotation of the rotating shaft 200 is kept, the introduction of said inert gas or said nitrogen gas and the injection of said first and second reaction gases are kept, and a direct current voltage between the anode plate 310 and the cathode 330 is applied so that a plasma of the inert gas or the nitrogen gas is ejected from one end of the channel 360 near to the base 100 along the extending direction of the channel 360, thereby reacting the first reaction gas with the second reaction gas to form an inorganic barrier layer 40 covering the isolation pillars 31 on the OLED substrate 30.

Specifically, in the preferred embodiment of the present invention, the gas introduced into the cavity 321 through said gas inlet 380 is an inert gas, and said inert gas is argon (Ar) gas. Said first reaction gas is ammonia gas. Said second reaction gas is silane. Correspondingly, in said step S4, the introduction of argon gas and the injection of ammonia gas and silane are kept, and the rotation of the rotating shaft 200 is kept. A direct current voltage is applied between the anode plate 310 and the cathode 330 to generate an electric field, so that the argon gas is converted into the plasma of the argon gas and ejected from one end of the channel 360 near to the base 100 in the extending direction of the channel 360, and the ammonia gas injected under the channel 360 near to the one end of the base 100 is converted to a plasma of the ammonia gas and mixed with a plasma of the argon gas to continue to be ejected under the anode plate 310 in the extending direction of the channel 360. The inorganic barrier layer 40 covering the isolation pillars 31 is made of silicon nitride on the OLED substrate 30. Meanwhile, since the argon plasma is ejected from the extending direction of the channel 360, and the OLED substrate 30 is kept rotated during the film formation. Therefore, even if the height of the isolation pillar 31 is much larger than the thickness of the inorganic barrier layer 40 finally formed, and the cross-sectional shape of the isolation pillars 31 is an inverted trapezoid, the inorganic barrier layer 40 is not thin or break on the side surface of the isolation pillars 31 so as to continuously cover the OLED substrate 30, thereby effectively improving the encapsulation effect.

Preferably, in said step S4, the direction of the inert gas or the nitrogen gas introduced into the cavity 321 by said gas inlet 380 is consistent with the extending direction of the cathode 330.

Preferably, in said step S3 and said step S4, said second reaction gas injection port 370 injects said second reaction gas under said anode plate 310 from top to bottom, and an included angle between a straight line where said second reaction gas is injected under said anode plate 310 and said horizontal plane is smaller than an included angle between a straight line where said extending direction of said channel 360 is located and said horizontal plane. Further, it is ensured that the thickness of the inorganic barrier layer 40 is not reduced or broken at the side surfaces of the isolation pillars 31, so as to further improve the encapsulation effect.

In summary, the plasma enhanced chemical vapor deposition apparatus according to the present invention has a straight line, where an extending direction of the cathode is located, oblique to the horizontal plane. The anode plate, the grid plate and the insulating plate are provided with the channel communicating with the cavity and extending in the same direction as the extending direction of the cathode. Therefore, when the apparatus is used for encapsulating an OLED panel, the rotating shaft is driven to rotate the OLED substrate, inert gas or nitrogen gas is injected into the cavity, and a first reaction gas is injected under one end of the channel near to the base. A second reaction gas is injected under the anode plate through the second reaction gas injection port and a direct current voltage is applied between the anode plate and the cathode, so that a plasma of inert gas or nitrogen gas is ejected from the end of the channel near the base in an extending direction of the channel to react the first reaction gas with the second reaction gas to form a continuous inorganic barrier layer on the surface of the OLED substrate having the isolation pillar, which effectively improves the encapsulation effect. In the encapsulation method of the OLED panel of the present invention, the above-mentioned plasma enhanced chemical vapor deposition apparatus can deposit a continuous inorganic barrier layer on the OLED substrate having isolation pillars on the surface to improve the encapsulation effect.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A plasma enhanced chemical vapor deposition apparatus, comprising: a base, a rotating shaft fixed on a lower surface of said base, and a plurality of reaction units disposed over said base;
each of said reaction units comprises a horizontal anode plate, a cavity defining layer disposed over said anode plate, a columnar cathode disposed over said anode plate, a plurality of grid plates and insulating plates disposed between said anode plate and said cavity defining layer as well as said cathode and sequentially and alternately overlapped from bottom to top;
said cavity defining layer is provided with a cavity penetrating said cavity defining layer, and said cathode is accommodated in said cavity; said anode plate and said plurality of grid plates and insulating plates are provided with channels communicating with said cavity, a straight line where an extending direction of said cathode is located is oblique to a horizontal plane, extending direction of said channel is consistent with said extending direction of said cathode;
each of said reaction unit further comprises: a first reaction gas injection port provided at one end of said channel near to said base, a gas inlet provided at one end of said cavity far away from said base, and a second reaction gas injection port provided under said anode plate; said gas inlet is used for introducing inert gas or nitrogen gas into said cavity; said first reaction gas injection port is used for injecting a first reaction gas under one end of said channel near to said base; said second reaction gas injection port is used for injecting a second reaction gas under said anode plate.

2. The plasma enhanced chemical vapor deposition apparatus according to claim 1, wherein said second reaction gas injection port injects said second reaction gas under said anode plate from top to bottom, and an included angle between a straight line where said second reaction gas is injected under said anode plate and said horizontal plane is smaller than an included angle between a straight line where said extending direction of said channel is located and said horizontal plane.

3. The plasma enhanced chemical vapor deposition apparatus according to claim 1, wherein said inert gas is argon gas, said first reaction gas is a mixed gas of one or more of ammonia gas, hydrogen gas, and nitrous oxide gas, and said second reaction gas is silane.

4. The plasma enhanced chemical vapor deposition apparatus according to claim 1, wherein a direction of said inert gas or said nitrogen gas introduced into said cavity by said gas inlet is consistent with said extending direction of said cathode.

5. The plasma enhanced chemical vapor deposition apparatus according to claim 1, wherein said extending direction of said cavity is consistent with said extending direction of said cathode.

6. An encapsulation method of an OLED panel, comprising following steps:
step S1, providing a plasma enhanced chemical vapor deposition apparatus as claimed in claim 1, a mask plate (20), and an OLED substrate (30);
a plurality of isolation pillars (31) are disposed on said OLED substrate (30);
step S2, disposing said OLED substrate (0) on said base, aligning said mask plate (20) with said OLED substrate (30), and fixing said mask plate (20) on said base;
step S3, driving said rotating shaft to rotate said base and said OLED substrate (30) on said base; utilizing an gas inlet to inject inert gas or nitrogen gas into a cavity, utilizing a first reaction gas injection port to inject a first reaction gas under one end of a channel near to said base, utilizing a second reaction gas injection port to inject a second reaction gas under said anode plate;
step S4, keeping said rotation of said rotating shaft, and keeping said introduction of said inert gas or nitrogen gas and said injection of said first and second reaction gases to apply a direct current voltage between said anode plate and said cathode, so as to make plasma of said inert gas or said nitrogen gas ejected from said end of said channel near to said base in an extending direction of said channel, thereby reacting said first reaction gas with said second reaction gas to form an inorganic barrier layer (40) covering said isolation pillars (31) on said OLED substrate (30).

7. The encapsulation method of the OLED panel according to claim 6, wherein in said step S3 and said step S4, said second reaction gas injection port injects said second reaction gas under said anode plate from top to bottom, and an included angle between a straight line where said second reaction gas is injected under said anode plate and said horizontal plane is smaller than an included angle between a straight line where said extending direction of said channel is located and said horizontal plane;
a cross-sectional shape of said isolation pillars (31) is an inverted trapezoid; an acute angle between a side surface of said isolation pillars (31) and said horizontal plane is greater than an included angle between a straight line where said extending direction of said channel is located and a horizontal plane.

8. The encapsulation method of the OLED panel according to claim 6, wherein said inert gas is argon gas, said first reaction gas is a mixed gas of one or more of ammonia gas, hydrogen gas, and nitrous oxide gas, and said second reaction gas is silane.

9. The encapsulation method of the OLED panel according to claim 6, wherein in said step S3 and said step S4, a direction of said inert gas or said nitrogen gas introduced into said cavity by said gas inlet is consistent with said extending direction of said cathode.

10. The encapsulation method of the OLED panel according to claim 6, wherein said extending direction of said cavity is consistent with said extending direction of said cathode.

11. A plasma enhanced chemical vapor deposition apparatus; comprising: a base, a rotating shaft fixed on a lower surface of said base, and a plurality of reaction units disposed over said base;
each of said reaction units comprises a horizontal anode plate, a cavity defining layer disposed over said anode plate, a columnar cathode disposed over said anode plate, and a plurality of grid plates and insulating plates disposed between said anode plate and said cavity defining layer as well as said cathode and sequentially and alternately overlapped from bottom to top;
said cavity defining layer is provided with a cavity penetrating said cavity defining layer, and said cathode is accommodated in said cavity; said anode plate and said plurality of grid plates and insulating plates are provided with channels communicating with said cavity, a straight line where an extending direction of said cathode is located is oblique to a horizontal plane, and an extending direction of said channel is consistent with said extending direction of said cathode;
each of said reaction unit further comprises: a first reaction gas injection port provided at one end of said channel near to said base, a gas inlet provided at one end of said cavity far away from said base, and a second reaction gas injection port provided under said anode plate; said gas inlet is used for introducing inert gas or nitrogen gas into said cavity; said first reaction gas injection port is used for injecting a first reaction gas under one end of said channel near to said base; said second reaction gas injection port is used for injecting a second reaction gas under said anode plate;
wherein said second reaction gas injection port injects said second reaction gas under said anode plate from top to bottom, and an included angle between a straight line where said second reaction gas is injected under said anode plate and said horizontal plane is smaller than an included angle between a straight line where said extending direction of said channel is located and said horizontal plane;
wherein said inert gas is argon gas, said first reaction gas is a mixed gas of one or more of ammonia gas, hydrogen gas, and nitrous oxide gas, and said second reaction gas is silane;
wherein a direction of said inert gas or said nitrogen gas introduced into said cavity by said gas inlet is consistent with said extending direction of said cathode;
wherein said extending direction of said cavity is consistent with said extending direction of said cathode.
